(19) United States
(12) Patent Application Publication
(10) Pub. No.: US 2010/0300520 A1
(43) Pub. Date: Dec. 2, 2010

(54) PHOTOVOLTAIC CELL HAVING NANODOTS AND METHOD FOR FORMING THE SAME

(75) Inventors: WEI-FANG SU, TAIPEI (TW); JWO-HUEI JOU, TAIPEI (TW); WEI-BEN WANG, TAIPEI (TW); JHIH-FONG LIN, TAIPEI (TW)

Correspondence Address: WPAT, PC;INTELLECTUAL PROPERTY ATTORNEYS, 7225 BEVERLY ST., ANNANDALE, VA, 22003, US

(73) Assignee: NATIONAL TAIWAN UNIVERSITY, TAIPEI (TW)

(21) Appl. No.: 12/497,611

(22) Filed: Jul. 3, 2009

(30) Foreign Application Priority Data
May 26, 2009 (TW) 098117392

(51) Int. Cl. H01L 31/00; H01L 51/46

(52) U.S. Cl. 136/256; 438/82; 257/E51.027; 977/773

(57) ABSTRACT

The present invention provides a photovoltaic cell comprising a photovoltaic conversion layer and a pair of electrodes. The photovoltaic conversion layer, being capable of converting incident light into a plurality hole-electron pairs, comprises a hole transport layer including a plurality of nanodots mixed therein for transporting the holes generated from the photovoltaic effect. The pair of electrodes are coupled respectively to two sides of the photovoltaic conversion layer for conducting holes and electrons. In another embodiment, the present invention further provides a method for forming the photovoltaic cell, wherein the nanodots are mixed in a solution formed of a hole transport material and then a hole transport layer having the nanodots is formed on a conductive substrate. In the photovoltaic cell having nanodots of the present invention, the hole mobility is enhanced so as to improve the efficiency of the photovoltaic cell.

### FIELD OF THE PRESENT INVENTION

The present invention generally relates to a photovoltaic cell technology and, more particularly, to a photovoltaic cell having nanodots with increased hole transport efficiency and a method for forming the photovoltaic cell.

### BACKGROUND OF THE PRESENT INVENTION

As the amounts of conventional resources such as electricity, coal and petroleum are limited, the resource problems have become a bottleneck of economic growth. More and more countries have launched researches on solar energy as a potential motive force for economic development. The solar energy, as a renewable energy resource, has attracted tremendous amount of attention. The solar energy is realized using photovoltaic cells with less power consumption and environment friendliness. In recent years, with the increasing demand in the solar energy, the manufacturing technology of photovoltaic cells has advanced significantly. Therefore, the solar energy has been the fastest developing industry.

In order to convert the solar energy into electrical energy, the photovoltaic cells are inevitable. The photovoltaic cell is a diode device with a p-n semiconductor junction, whereat the photovoltaic effect is used to generate electricity. When a photon is absorbed on the surface of a diode to generate excitons, the built-in electric field in the depletion region at the p-n junction unbind the excitons to generate electrons and holes transmitted to respective electrodes to induce a current and thus construct a photovoltaic cell.

Because of the importance of the photovoltaic cell, lots of efforts have been made on the efficiency as well as manufacturing of the photovoltaic cell in a material aspect to achieve efficient and rapid carrier transport. Recently, the studies on the photovoltaic cell are emphasized on organic photovoltaic cells having an organic conductive polymer material mixed with an inorganic nano material to form a thin film as the photo-sensitive and electricity generation material. Compared to the conventional photovoltaic cell using inorganic p-n semiconductor, the organic photovoltaic cell can be made with low cost by ink-injection or dip coating on the substrate. Moreover, with the manufacturing steps mentioned above, the organic photovoltaic cell can be formed on a flexible substrate with lightweight and high flexibility.

In U.S. Pub. No. 2003/0226498, a photovoltaic cell structure formed using a photovoltaic thin film comprising semiconductor nano crystals and an organic material is disclosed. In this prior art, the photovoltaic thin film comprises an organic semiconductor polymer (such as P3HT) material mixed with semiconductor nano crystals (such as CdSe). Moreover, U.S. Pub. No. 2008/0128021 also discloses an organic photovoltaic thin film comprising a nano composite material. In this prior art, the organic material layer is mixed with nano particle materials such as quantum dots, core-shell semiconductor nano particles or microstructures with supports such as bipods, tripods or tetrapods to enhance the photovoltaic effect.

Even though there have been lots of reports on organic photovoltaic materials, the conductive polymer exhibits high hole mobility. Therefore, electrons accumulated in the active layer tend to recombined with the holes to lower the efficiency of the photovoltaic device. Accordingly, there is need in providing a photovoltaic cell and a method for manufacturing the same to overcome the aforesaid problems.

### SUMMARY OF THE PRESENT INVENTION

The present invention provides a photovoltaic cell having nanodots and a method for forming the photovoltaic cell, wherein the hole transport material of the photovoltaic cell is mixed with nanodots to form a photovoltaic thin film. The photovoltaic cell using such a photovoltaic thin film exhibits enhanced hole mobility to improve the efficiency of the photovoltaic cell.

In one embodiment, the present invention provides a photovoltaic cell comprising: a photovoltaic conversion layer, being capable of converting incident light into a plurality hole-electron pairs, comprising a hole transport layer including a plurality of nanodots mixed therein for hole transport; and a first electrode and a second electrode, being coupled respectively to two sides of the photovoltaic conversion layer for conducting holes and electrons.

In another embodiment, the present invention further provides a method for forming a photovoltaic cell, comprising steps of: adding nanodots to a hole transport solution; coating a first electrode with the hole transport solution thereon to form a hole transport layer; coating the hole transport layer with a polymer material mixed with an inorganic material thereon to form an active layer; forming a hole blocking layer on the active layer; and forming a second electrode on the hole blocking layer.

### BRIEF DESCRIPTION OF THE DRAWINGS

The objects and spirits of several embodiments of the present invention will be readily understood by the accompanying drawings and detailed descriptions, wherein:

FIG. 1A schematically depicts a photovoltaic cell according to the present invention;

FIG. 1B shows the energy band diagrams of the photovoltaic cell in FIG. 1A;

FIG. 2 schematically depicts a nanodot according to the present invention;

FIG. 3 schematically depicts a photovoltaic cell according to another embodiment of the present invention;

FIG. 4 is a flowchart of a method for forming a photovoltaic cell according to the present invention;

FIG. 5 schematically depicts a transfer reaction on the surface of a nanodot; and

FIG. 6 shows the power conversion rate profiles as a comparison between the present invention using nanodots and the prior art without nanodots.

### DETAILED DESCRIPTION OF THE PREFERRED EMBODIMENT

The present invention can be exemplified but not limited by various embodiments as described hereinafter.

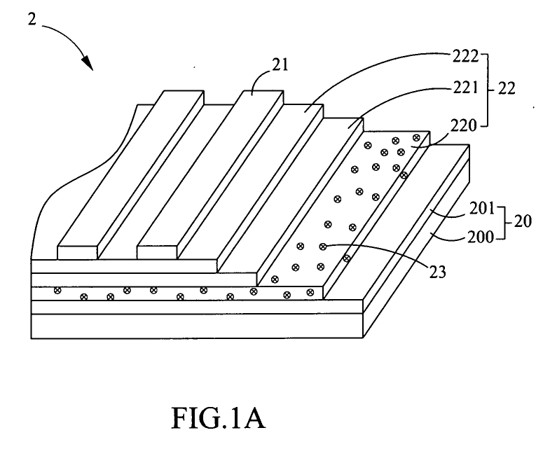

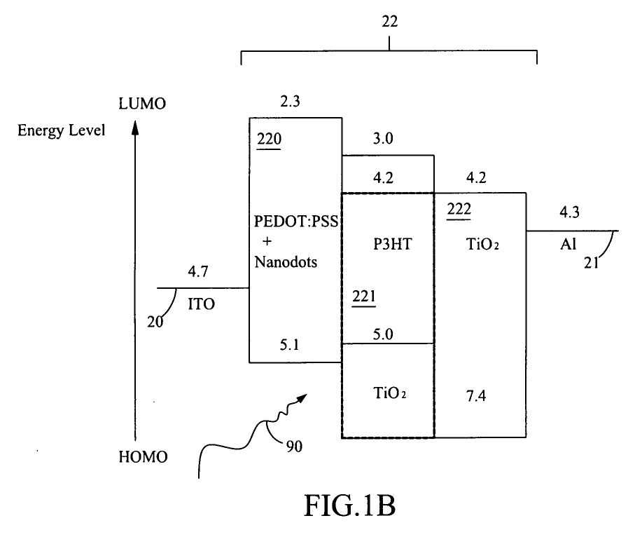

Please refer to FIG. 1A, which schematically depicts a photovoltaic cell according to the present invention. In the present embodiment, the photovoltaic cell 2 comprises a first electrode 20, a second electrode 21 and a photovoltaic conversion layer 22 disposed between the first and second electrodes 20 and 21 so as to convert incident light into a plurality of hole-electron pairs. In the present embodiment, the first electrode 20 is a transparent electrode comprising a substrate 200 and a conductive layer 201 formed on the substrate 200. The substrate 200 may be a transparent substrate, such as a glass substrate or a plastic substrate. The conductive layer 201 may comprise a transparent conductive material such as indium-tin oxide (ITO), aluminum-zinc oxide (AZO) or zinc oxide (ZnO), but is not limited thereto. In the present embodiment, the conductive layer 200 comprises ITO.

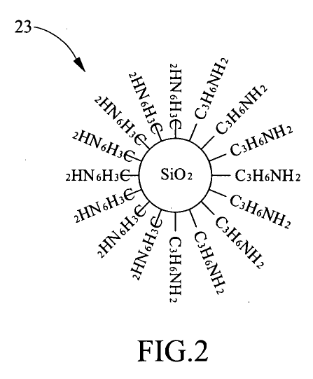

The photovoltaic conversion layer 22 comprises a hole transport layer 220, an active layer 221 and a hole blocking layer 222. The hole transport layer 220 is formed on the first electrode to conducting holes to the first electrode 20. The hole transport layer 220 may comprise a p-type polymer organic material or a p-type semiconductor material. In the present embodiment, the hole transport layer 220 comprise PEDOT:PSS, but is not limited thereto. Moreover, the hole transport layer 220 is mixed with a plurality of nanodots 23 to enhance the hole transport efficiency of the hole transport layer to further the efficiency of the photovoltaic cell. Please refer to FIG. 2, which schematically depicts a nanodot according to the present invention. In the present embodiment, the nanodot 23 is a polymeric nanodot (PND). The nanodot 23 in FIG. 2 comprises polymer at the center. In the present embodiment, the nanodot 23 is silicon dioxide (SiO₂) polymer with amino groups (NH₂—) disposed around the nanodot 23.

Returning to FIG. 1A, the active layer 221 is formed on the hole transport layer 220. In the present embodiment, the active layer 221 comprises an inorganic material and an organic material mixed with each other. The inorganic material may comprise nano particles, quantum dots, nano tubes, nano wires or nano rods. In the present embodiment, the inorganic material comprises titanium dioxide (TiO2) nano rods, but is not limited to titanium dioxide. The organic material comprises conductive polymer material such as poly(3-hexylthiophene) (P3HT), poly(cyclopentadithiophene-co-benzothiadiazole) or poly[2-methoxy-5-(2′-ethyl-hexyloxy)-1,4-phenylene vinylene] (MEH-PPV), but is not limited thereto. In the present embodiment, the active layer comprises P3HT mixed with titanium dioxide (TiO2) nano rods. The hole blocking layer 222 is formed on the active layer 221. The hole blocking layer 222 comprises an inorganic material, which may comprise nano particles, quantum dots, nano tubes, nano wires or nano rods. In the present embodiment, the hole blocking layer 222 comprises titanium dioxide (TiO2) nano rods. The second electrode 21 is formed on the hole blocking layer 222. The second electrode 21 may be transparent or opaque. Similar to the first electrode, the transparent electrode comprises conductive metal such as aluminum (Al) or gold (Au) if the second electrode 21 is opaque, but is not limited thereto.

In FIG. 1B for the energy band diagrams of the photovoltaic cell in FIG. 1A, when the photovoltaic cell of the present invention is excited by the light 90, the excitons at the interface in the active layer 221 (P3HT-TiO₂) are separated into paired electrons and holes. The electrons are conducted through the hole blocking layer 222 (TiO₂) into the second electrode 21 (Al), while the holes are conducted through the conductive polymer (P3HT in the present embodiment) into the hole transport layer 220 (PEDOT:PSS) and output from the first electrode 20 (ITO). During carrier transport, since the electron mobility in the hole blocking layer 222 (TiO₂) for transporting electrons is much higher than the hole mobility in the conductive polymer (P3HT), it is very likely that the electrons are accumulated in the active layer 221 to cause recombination of the electrons and the holes and thus significant reduction of the efficiency of the photovoltaic cell. Accordingly, in the present invention, the hole transport layer 220 is mixed with nanodots to balance the electron mobility and the hole mobility to avoid recombination of the electrons and the holes and thus enhance the efficiency of the photovoltaic cell.

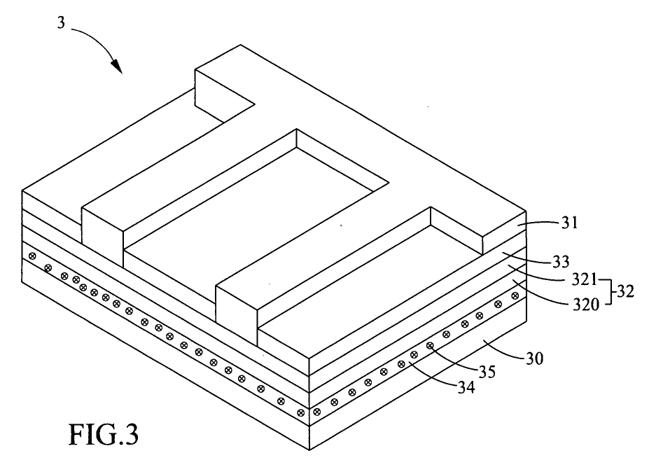

Please refer to FIG. 3, which schematically depicts a photovoltaic cell according to another embodiment of the present invention. The photovoltaic cell 3 of the present embodiment is an inorganic photovoltaic cell comprising a semiconductor material with a p-n junction. The photovoltaic cell 3 comprises a first electrode 30, a second electrode 31 and a photovoltaic conversion layer 32 between the first electrode 30 and the second electrode 31. The photovoltaic conversion layer 32 comprises a p-type semiconductor material 320 and a n-type semiconductor material 32. Furthermore, an anti-reflection layer 33 with low reflectivity is disposed between the n-type semiconductor material 321 and the second electrode 31 to reduce reflection loss so that photovoltaic reactions take place after the light enters the photovoltaic cell 3. The first electrode 30 and the second electrode 31 are similar to the electrode in FIG. 1A, and descriptions thereof are not presented herein. Moreover, a hole transport layer 34 is provided between the p-type semiconductor material 320 and the first electrode 30. The hole transport layer 34 is mixed with nanodots 35 comprising polymer. In the present embodiment, the nanodots comprising silicon dioxide polymer with amino groups (NH₂—).

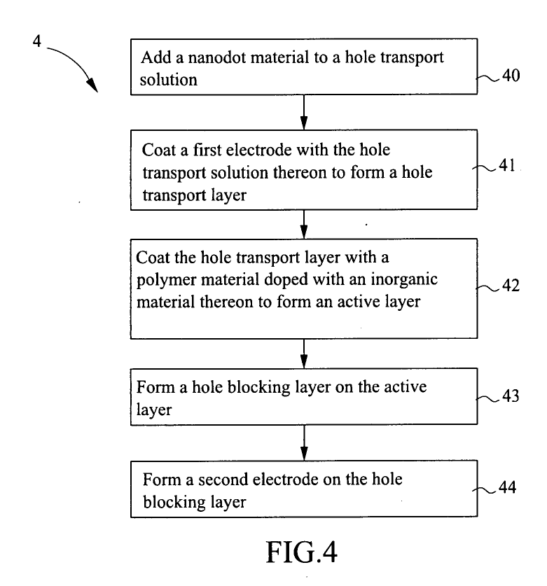

Please refer to FIG. 4, which is a flowchart of a method for forming a photovoltaic cell according to the present invention. The flowchart 4 comprises steps as described herein. Firstly, step 40 is performed to add a nanodot material to a hole transport solution. The hole transport solution is a polymer solution, exemplified by PEDOT:PSS, but not limited thereto. The nanodot material comprises polymer with functional groups, such as silicon dioxide polymer with amino groups (NH₂—). The nanodot material is formed by performing a transfer reaction on polymeric nanodots comprising hydroxyl groups (OH—) to obtain polymeric nanodots with the amino groups (NH₂—). The transfer reaction is achieved using 3-aminopropyltriethoxysilane (APTES), but is not limited thereto.

Then, in step 41, a first electrode is coated with the hole transport solution thereon to form a hole transport layer. The first electrode is transparent and comprises a conductive material such as indium-tin oxide (ITO), aluminum-zinc oxide (AZO) and zinc oxide (ZnO). The hole transport layer is formed on the first electrode by conventional techniques such as spin coating, spray coating and blade coating. In step 42, the hole transport layer is coated with a polymer material mixed with an inorganic material thereon to form an active layer. The active layer is formed by conventional coating techniques or injection. These conventional coating techniques include spin coating, spray coating and blade coating. The injection process is performed by mixing and liquidizing the polymer and inorganic particles at high temperatures and injecting the same using a injecting apparatus to form an active layer on the hole transport layer. Then, step 43 is performed to form a hole blocking layer on the active layer. The hole blocking layer is formed by coating the active layer with a titanium dioxide nano rod solution. Finally, in step 44, a second electrode is formed on the hole blocking layer. The second electrode may also be formed by evaporation or sputtering.

### MANUFACTURING EXAMPLE

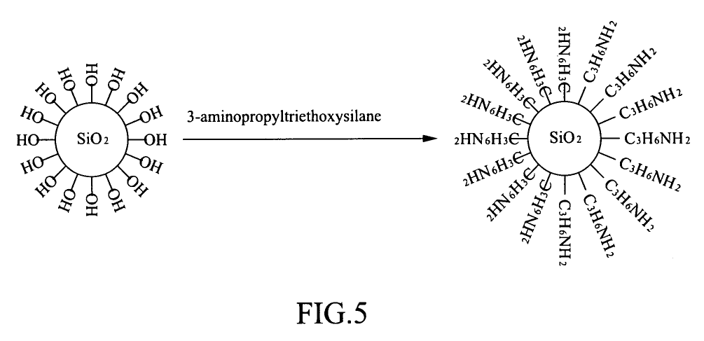

At the first stage, polymeric nanodots are manufactured by synthesis. Firstly, 60 g of sodium metasilicate (Na₂SiO₃) and 200 mL of 2.5M hydrochloric acid (HCl) are added to 200 mL of de-ionized water and the solution is stirred at 0° C. for 5 minutes. Then, 200 mL of tetrahydrofuran (C₄H₈O) and 60 g of sodium chloride (NaCl) are added to the solution and the solution is stirred for 10 minutes. Then, the solution is left alone for 10 minutes to separate into layers so that tetrahydrofuran-containing solution is extracted. 30 g of sodium sulfate (Na₂SO₄) is added to the tetrahydrofuran-containing solution to remove surplus water. Then the solution is left alone for hours to separate into layers. The top layer solution containing polymeric nanodots with hydroxyl groups (OH—) is extracted, as shown in FIG. 5. The polymeric nanodots with hydroxyl groups are mixed with 3-aminopropyltriethoxysilane (APTES) to obtain polymeric nanodots with amino groups (NH₂—).

At the second stage, titanium dioxide nano rods are manufactured. According to T-W Zeng et al. “A large interconnecting network within hybrid MEH-PPV/TiO2 nanorod photovoltaic devices”, Nanotechnology, 17, 5387, 2006, 120 g of oleic acid (OA, 90%, Aldrich) is provided in a three-neck bottle, where argon is input for several minutes to ensure it is an inert environment. The reaction bottle is heated up to 120° C. for one hour and then cooled down to 90° C. 17 mmol of titanium isopropoxide (98%, Aldrich) is added to the reaction bottle at 90° C. After 5 minutes, a solution containing trimethylamine-N-oxide dehydrate (98%, Acros) (34 mmol/H₂O 17 ml) is added to cause reaction for about 9 hours and then the reaction bottle is cooled down to the room temperature. Ethanol (99.8%, Aldrich) is used to wash away the reacted solvent and the unreacted material. A centrifugator is used to separate the sediments from the solvent. The sediments are the desired titanium dioxide nano rods.

At the second stage, a photovoltaic cell mixed with nanodots is manufactured. ITO glass is cleaned by ultrasonic cleaning in a solution of methanol and ammonia:hydrogen peroxide:de-ionized water=1:1:5 for 30 minutes and in isopropanol for one hour. The nanodots synthesized at the first stage is diluted by tetrahydrofuran (THF) into solutions with different weight percentages and is then added to the hole transport layer solution comprising PEDOT:PSS (Bayer Batron-P) to be stirred. The mixed solution is formed on the cleaned ITO glass by spin coating and then baked at 120° C. for 20 minutes. 9 mg of conductive polymer comprising poly(3-hexylthiophene) (P3HT) is dissolved in 0.3 mL chlorobezene under stirring at 50° C. until P3HT is completely dissolved in chlorobezene. Meanwhile, the titanium dioxide (TiO₂) nano rod solution manufactured at the second stage is added to hexane and centrifugated to extract 15 mg of titanium dioxide nano rods, which are added to 0.2 mL of pyridine, 0.4 mL of dichloromethane and 0.6 mL of chlororform for ultrasonic cleaning. Then, 1.2 mL of the titanium dioxide nano rod solution is added to the P3HT solution and is stirred. The solution comprising organic conductive polymer and inorganic semiconductor is formed by spin coating on the hole transport layer that has been baked. Furthermore, an additional titanium dioxide nano rod solution is formed by spin coating on the active layer to form a hole blocking layer. Finally, an aluminum electrode layer is evaporated onto the surface of the device to form a photovoltaic cell as shown in FIG. 1A.

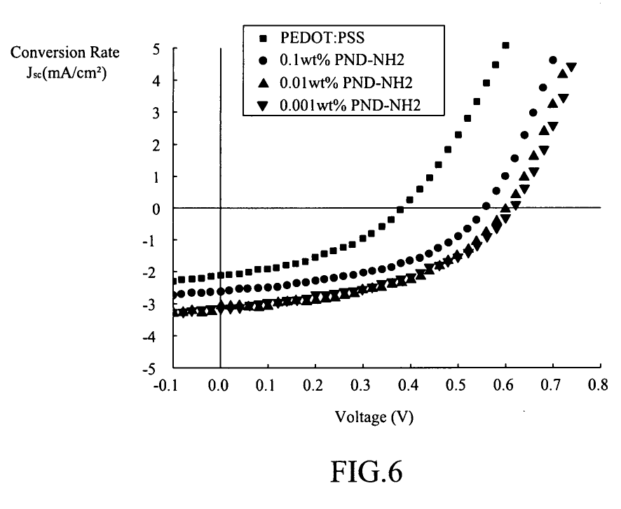

Please refer to FIG. 6 and Table 1. In FIG. 6, ▪ denotes the conversion efficiency with respect to the hole transport layer without being mixed with nanodots, denotes the conversion efficiency with respect to the hole transport layer mixed with 0.1 wt % polymeric nanodots (PND-NH2), ▴ denotes the conversion efficiency with respect to the hole transport layer mixed with 0.01 wt % polymeric nanodots (PND-NH2), and ▾ denotes the conversion efficiency with respect to the hole transport layer mixed with 0.001 wt % polymeric nanodots (PND-NH2). According to FIG. 6, it is obvious that the open-circuit voltage and the short-circuit current are increased to enhance the photovoltaic conversion efficiency when the hole transport layer is mixed with nanodots. It is thus evident that adding nanodots to the hole transport layer improves the efficiency of the photovoltaic cell comprising organic conductive polymer P3HT mixed with inorganic semiconductor nano rods (titanium dioxide).

TABLE 1
P3HT-TiO₂ photovoltaic cell performances with different weight
percentages of nanodots added to the hole transport layer

| Sample | VOC(V) | JSC(mA/cm2) | FF(%) | EFF(%) |
|---|---|---|---|---|
| PEDOT:PSS | 0.39 | 2.15 | 39.97 | 0.33 |
| 0.1 wt % P—N D-NH2 | 0.56 | 2.66 | 45.53 | 0.68 |
| 0.01 wt % P—N | 0.60 | 3.09 | 47.68 | 0.89 |
| D-NH2 | | | | |
| 0.001 wt % P—N | 0.62 | 3.13 | 44.99 | 0.87 |
| D-NH2 | | | | |

Accordingly, the present invention discloses a photovoltaic cell having nanodots with increased hole transport efficiency and a method for forming the photovoltaic cell. Therefore, the present invention is novel, useful, and non-obvious.

Although this invention has been disclosed and illustrated with reference to particular embodiments, the principles involved are susceptible for use in numerous other embodiments that will be apparent to persons skilled in the art. This invention is, therefore, to be limited only as indicated by the scope of the appended claims.

What is claimed is:

1. A photovoltaic cell, comprising:
a photovoltaic conversion layer, being capable of converting incident light into a plurality hole-electron pairs, comprising a hole transport layer including a plurality of nanodots mixed therein for hole transport; and
a first electrode and a second electrode, being coupled respectively to two sides of the photovoltaic conversion layer for conducting holes and electrons.

2. The photovoltaic cell as recited in claim 1, wherein the photovoltaic conversion layer is a semiconductor material layer having a p-n junction or an organic photovoltaic conversion layer.

3. The photovoltaic cell as recited in claim 2, wherein the hole transport layer is formed between a p-type portion of the semiconductor material layer and the first electrode.

4. The photovoltaic cell as recited in claim 2, wherein the hole transport layer is a p-type conductive polymer material mixed with the plurality of nanodots therein.

5. The photovoltaic cell as recited in claim 1, wherein the photovoltaic conversion layer further comprises:
a hole blocking layer, being coupled to the second electrode; and
an active layer, being disposed between the hole transport layer and the hole blocking layer being coupled to each other.

6. The photovoltaic cell as recited in claim 5, wherein the active layer comprises a polymer material and an inorganic material.

7. The photovoltaic cell as recited in claim 5, wherein the hole blocking layer comprises an inorganic material.

8. The photovoltaic cell as recited in claim 5, wherein the hole transport layer comprises an organic material.

9. The photovoltaic cell as recited in claim 1, wherein the first electrode is a transparent electrode.

10. The photovoltaic cell as recited in claim 9, wherein the transparent electrode further comprises a transparent substrate coated with a conductive material thereon.

11. The photovoltaic cell as recited in claim 1, wherein the nanodots comprise amino groups (NH₂—).

12. A method for forming a photovoltaic cell, comprising steps of:
adding nanodots to a hole transport solution;
coating a first electrode with the hole transport solution thereon to form a hole transport layer;
coating the hole transport layer with a polymer material mixed with an inorganic material thereon to form an active layer;
forming a hole blocking layer on the active layer; and
forming a second electrode on the hole blocking layer.

13. The method as recited in claim 12, wherein the hole transport solution comprises an organic material.

14. The method as recited in claim 12, wherein the first electrode is a transparent electrode.

15. The method as recited in claim 12, wherein the transparent electrode further comprises a transparent substrate coated with indium-tin oxide (ITO) thereon.

16. The method as recited in claim 12, wherein the nanodots comprise amino groups (NH₂—).

17. The method as recited in claim 16, wherein the nanodots are formed by performing a transfer reaction on polymeric nanodots comprising hydroxyl groups (OH—) to obtain polymeric nanodots with the amino groups (NH₂—).

18. The method as recited in claim 17, wherein the transfer reaction is achieved using 3-aminopropyltriethoxysilane (APTES).

19. The method as recited in claim 12, wherein the hole blocking layer comprises an inorganic material.
